(19) United States
(12) Patent Application Publication
(10) Pub. No.: US 2025/0273583 A1
(43) Pub. Date: Aug. 28, 2025

(54) INTERPOSER DEVICE AND SEMICONDUCTOR PACKAGE DEVICE

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Liang-Kai CHEN, HSINCHU CITY (TW); Yuan-Hung LIN, HSINCHU CITY (TW); Sheng-Fan YANG, HSINCHU CITY (TW); Chih-Chiang HUNG, HSINCHU CITY (TW); Wen-Yi JIAN, HSINCHU CITY (TW); Shih-Hsuan HSU, HSINCHU CITY (TW); Bi-Yang LI, HSINCHU CITY (TW)

(21) Appl. No.: 18/786,595

(22) Filed: Jul. 29, 2024

(30) Foreign Application Priority Data
Feb. 26, 2024 (TW) 113106855

(51) Int. Cl. H01L 23/538; H01L 23/00; H01L 25/065

(52) U.S. Cl. CPC H01L 23/5386; H01L 23/5383; H01L 25/0655; H01L 24/16; H01L 2224/16227; H01L 2224/16235

(57) ABSTRACT

An interposer device configured to provide the transmission of communication signals between two chips is provided. The interposer device comprises multiple circuit layers electrically connected between the two chips and arranged along a vertical direction. Each circuit layer is configured to take a first direction or a second direction as a signal transmission direction for transmitting the communication signals. The first direction is opposite to the second direction, and both the first and second directions are different from the vertical direction. Each circuit layer comprises signal lines and ground lines arranged alternately. The projections of the signal lines in one circuit layer along the vertical direction on an adjacent circuit layer overlap the ground lines in this adjacent circuit layer. In any three circuit layers sequentially arranged, the signal transmission direction of the first circuit layer is opposite to the signal transmission direction of the last circuit layer.

### RELATED APPLICATIONS

This application claims priority to Taiwan Application Serial Number 113106855, filed on Feb. 26, 2024, which is herein incorporated by reference in its entirety.

### BACKGROUND

### Technical Field

The present disclosure is related to signal interference technology within interposer devices. More particularly, the present disclosure is related to interposer devices and semiconductor package devices that use destructive interference to reduce communication crosstalk between conductive lines.

### Description of Related Art

In the field of advanced packaging technology, 2.5-dimensional (2.5D) interposer packaging, which is between two-dimensional (2D) interposer packaging and three-dimensional (3D) interposer packaging, is widely used. In 2.5D interposer packaging technology, multiple chips are arranged on the substrate through an interposer device, and these different chips can communicate with each other through the interposer device.

However, in interposer devices, coupling between conductive lines often causes crosstalk, which affects the quality of communication signals on the conductive lines. Furthermore, when the crosstalk between conductive lines satisfies the condition of constructive interference, it will further make the quality of communication signals on the conductive lines decline. Therefore, how to alleviate the impact of the crosstalk caused by constructive interference is one of the topics in this field.

### SUMMARY

An interposer device is provided in the present disclosure. The interposer device is configured to provide the transmission of a plurality of communication signals between two chips. The interposer device comprises a plurality of circuit layers. The plurality of circuit layers are electrically connected between the two chips and are arranged along a vertical direction. Each of the plurality of circuit layers is configured take a first direction or a second direction as a signal transmission direction for transmitting the plurality of communication signals. The first direction is opposite to the second direction, and both the first direction and the second direction are different from the vertical direction. Each of the plurality of circuit layers comprises a plurality of signal lines and a plurality of ground lines arranged alternately. The projections of the signal lines in one of the plurality of circuit layers along the vertical direction on an adjacent one of the plurality of circuit layers overlap the plurality of ground lines in the adjacent one of the plurality of circuit layers. In any three of the plurality of circuit layers sequentially arranged, the signal transmission direction of the first circuit layer is opposite to the signal transmission direction of the last circuit layer.

A semiconductor package device is provided in the present disclosure. The semiconductor package device comprises a first chip, a second chip, a package structure and an interposer device. The second chip is configured to transmit a plurality of communication signals with the first chip through a plurality of channels. The interposer device is electrically connected to the first chip, the second chip, the package substrate and comprises a plurality of circuit layers. The plurality of circuit layers are electrically connected between the first chip and the second chip to serve as the plurality of channels and are arranged along a vertical direction. Each of the plurality of circuit layers is configured take a first direction or a second direction as a signal transmission direction for transmitting the plurality of communication signals. The first direction is opposite to the second direction, and both the first direction and the second direction are different from the vertical direction. Each of the plurality of circuit layers comprises a plurality of signal lines and a plurality of ground lines arranged alternately. The projections of the signal lines in one of the plurality of circuit layers along the vertical direction on an adjacent one of the plurality of circuit layers overlap the plurality of ground lines in the adjacent one of the plurality of circuit layers. In any three of the plurality of circuit layers sequentially arranged, the signal transmission direction of the first circuit layer is opposite to the signal transmission direction of the last circuit layer.

Through the interposer device and the semiconductor package device of the present disclosure, by configuring the signal transmission direction of the signal lines in the circuit layers according to specific rules, the crosstalk between adjacent signal lines can be reduced due to destructive interference, thereby improving the performance of the signal lines in transmitting signals.

It should be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a schematic diagram of a semiconductor package device in accordance with some embodiments of the present disclosure.

FIG. 2 is a cross-sectional view of an interposer device in accordance with some embodiments of the present disclosure.

FIG. 3A is a schematic diagram of the communication signal transmission direction within the interposer device in accordance with some instances.

FIG. 3B is a schematic diagram of the crosstalk phenomenon around a signal line in accordance with the instance of FIG. 3A.

FIG. 4A is a schematic diagram of the communication signal transmission direction within the interposer device in accordance with some embodiments of the present disclosure.

FIG. 4B is a schematic diagram of the crosstalk phenomenon around a signal line in accordance with the instance of FIG. 4A.

FIG. 5 is a schematic diagram of the communication signal transmission direction within the interposer device in accordance with other embodiments of the present disclosure.

FIG. 6 is a schematic diagram of the communication signal transmission direction within the interposer device in accordance with yet other embodiments of the present disclosure.

### DETAILED DESCRIPTION

Reference will now be made in detail to the present embodiments of the disclosure, examples of which are illustrated in the accompanying drawings.

In the present disclosure, when an element is referred to as “connected”, it may mean “electrically connected” or “optical connected”. When an element is referred to as “coupled”, it may mean “electrically coupled” or “optical coupled”. “Connected” or “coupled” can also be used to indicate that two or more components operate or interact with each other. As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, steps, operations, elements and/or components, but the existence or addition of one or more other features, steps, operations, elements, components, and/or groups thereof are not excluded.

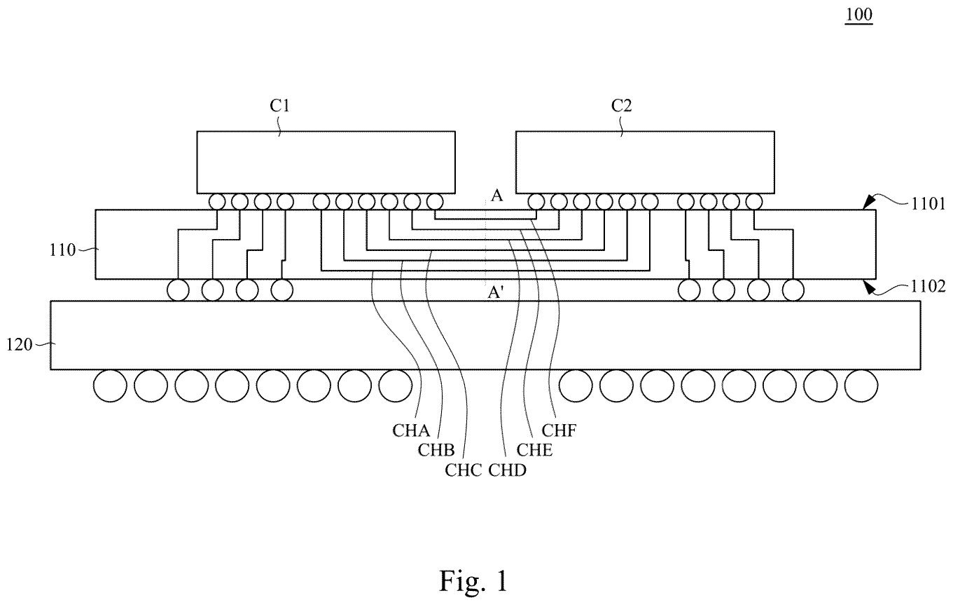

FIG. 1 is a schematic diagram of a semiconductor package device 100 in accordance with some embodiments of the present disclosure. In some embodiments, the semiconductor package device 100 comprises interposer device 110, a plurality of semiconductor devices (e.g., chips C1 and C2) and a package substrate 120.

In some embodiments, the chips C1 and C2 are electrically connected to the first surface 1101 of the interposer device 110, so as to transmit communication signals between each other through the channels CHA-CHF in the interposer device 110. The package substrate 120 is electrically connected to the second surface 1102 of the interposer device 110, and is configured to transmit power to the chips C1 and C2 through the interposer device 110, wherein the second surface 1102 is opposite to the first surface 1101.

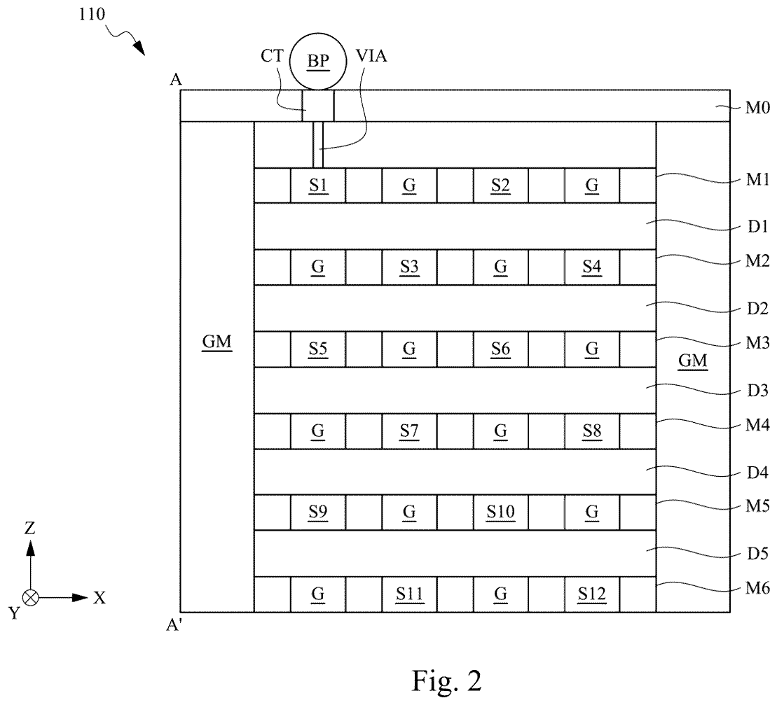

Regarding the internal structure of the interposer device 110, please further refer to FIG. 2. FIG. 2 is a cross-sectional view of the interposer device 110 along line A-A′ in accordance with some embodiments of the present disclosure. In some embodiments, the interposer device 110 comprises a redistribution layer M0, circuit layers M1-M6 and dielectric layers D1-D5. The redistribution layer M0 is arranged above the circuit layers M1-M6 along a vertical direction (direction Z). A plurality of signal contacts CT are arranged on the redistribution layer M0, and each of the signal contacts CT is electrically connected to the chips C1 and C2 through a micro-bump BP. In this way, the chips C1 and C2 can communicate with each other through the interposer device 110.

The circuit layers M1-M6 extend in a horizontal direction (directions X, Y) and are sequentially arranged from top to bottom along the vertical direction (direction Z), so as to realize the channels CHA-CHF of the interposer device 110 and provide the signal communication between the chips C1 and C2.

Each of the circuit layers M1-M6 comprises a plurality of signal lines and a plurality of ground lines, and these signal lines and ground lines are alternately arranged in each of the circuit layers M1-M6. Take the embodiment in FIG. 2 as an example, the circuit layer M1 comprises a signal line S1, a ground line G, a signal line S2 and another ground line G arranged in sequence; the circuit layer M2 comprises a ground line G, a signal line S3, another ground line G and a signal line S4 arranged in sequence; the circuit layer M3 comprises a signal line S5, a ground line G, a signal line S6 and another ground line G arranged in sequence; the circuit layer M4 comprises a ground line G, a signal line S7, another ground line G and a signal line S8 arranged in sequence; the circuit layer M5 comprises a signal line S9, a ground line G, a signal line S10 and another ground line G arranged in sequence; the circuit layer M6 comprises a ground line G, a signal line S11, another ground line G and a signal line S12 arranged in sequence.

In addition, for any one of the circuit layers M1-M6, the projection of the signal lines along the vertical direction (direction Z) on an adjacent circuit layer will overlap with the ground line in this adjacent circuit layer. Take the embodiment in FIG. 2 as an example, the projections of the signal lines S1 and S2 of the circuit layer M1 on the circuit layer M2 along the direction Z will respectively overlap with two ground lines G of the circuit layer M2.

In some embodiments, the signal lines S1-S12 have the same line width in the direction X, and the ground lines G have the same line width in the direction X. In some preferred embodiments, the line width of each of the signal lines is equal to the line width of each of the ground lines, but the present disclosure is not limited thereto. In some other embodiments of the present disclosure, the line width of each of the signal lines may not be equal to (e.g., less than) the line width of each of the ground lines.

In some embodiments, the spacing between the signal lines S1-S12 and an adjacent ground line G in the direction X are the same. Take the embodiment in FIG. 2 as an example, in the circuit layer M1, the spacing between the signal line S1 and its adjacent ground line G (i.e., on its right side) is equal to the spacing between the signal line S2 and its adjacent ground line G (i.e., on its left or right side).

As shown in FIG. 2, since the signal lines S1-S12 and the plurality of ground lines G extend along the direction Y, the communication signals can be transmitted forward (e.g., into the figure) or reversely (e.g., out of the figure) along the direction Y. In some embodiments, signal lines located on the same circuit layer transmit communication signals in the same direction. In other words, take the example in FIG. 2 as an example, the communication signals transmitted by the signal lines S1 and S2 are in the same direction, the communication signals transmitted by the signal lines S3 and S4 are in the same direction, and so on.

The dielectric layers D1-D5 are respectively disposed between the circuit layers M1-M6. For example, the dielectric layer D1 is disposed between the circuit layers M1 and M2, the dielectric layer D2 is disposed between the circuit layers M2 and M3, and so on. The dielectric layers D1-D5 are configured to shield the circuit layers M1-M6, so as to reduce interference between the communication signals in the circuit layers M1-M6.

In some embodiments, the interposer device 110 further comprises a plurality of vias VIA. These vias VIA are buried between the redistribution layer M0 and the circuit layers M1-M6, and are configured to make the signal contacts CT of the redistribution layer M0 to be electrically connected to the signal lines S1-S12 in the circuit layers M1-M6.

In some embodiments, the interposer device 110 further comprises a ground mesh GM. The ground mesh GM comprises two portions (e.g., two ground mesh GM blocks in FIG. 2) that at least partially surround the signal lines. S1-S12. In addition, the ground mesh GM is connected to the ground lines G, and thus the ground mesh GM can be configured to provide a ground voltage to the ground lines G.

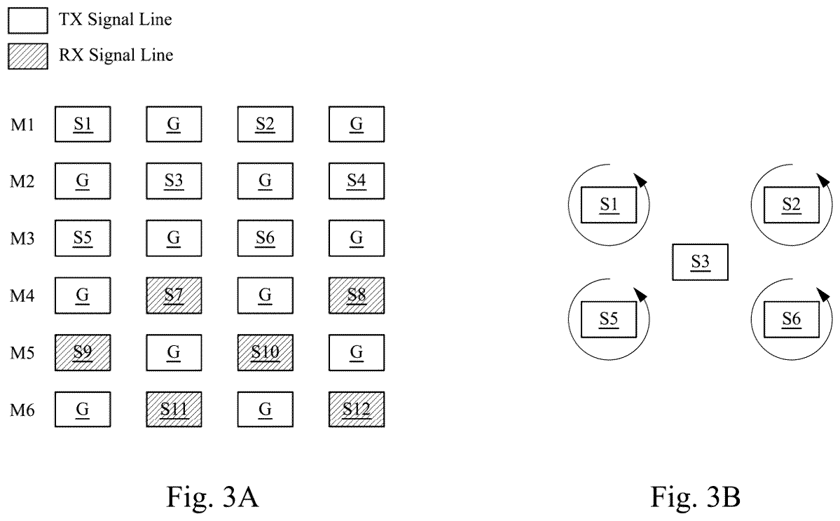

As mentioned above, the plurality of communication signals can be transmitted in two opposite directions in the signal lines S1-S12. For example, the chip C1 can transmit communication signals to the chip C2 through some of the signal lines S1-S12, and receive communication signals from the chip C2 through the others of the signal lines S1-S12. Please refer FIG. 3A. FIG. 3A is a schematic diagram of the communication signal transmission direction within the interposer device in accordance with some instances. For the sake of brevity of the figure, the redistribution layer M0, the dielectric layers D1-D5 and the vias VIA are omitted in FIGS. 3A, 4A, 5 and 6.

The instance illustrated in FIG. 3A is often implemented as a common configuration of the communication signal transmission of an interposer devices. Specifically, in the interposer device 110, the signal lines in the upper half (e.g., the signal lines S1-S6 in the circuit layers M1-M3) are configured as TX signal lines (i.e., signal lines that transmit communication signals, and are marked with dots in figure), while the signal lines in the lower half (e.g., the signal lines S7-S12 in the circuit layers M4-M6) are configured as RX signal lines (i.e., signal lines that receive communication signals, and are marked with diagonal lines in figure). In this way, the chip C1 can transmit communication signals to the chip C2 through the signal lines S1-S6, and receive communication signals from the chip C2 through the signal lines S7-S12. In some common and not shown instances, the configuration of the communication signal transmission directions may be opposite to the above-mentioned instance.

However, the above-mentioned common configuration of communication signal transmission directions will make the crosstalk between the signal lines satisfy the condition of constructive interference, thereby affecting the quality of communication signals. Please refer to FIG. 3B. FIG. 3B is a schematic diagram of the crosstalk phenomenon around the signal line S3 in accordance with the instance of FIG. 3A.

In FIG. 3B, the arrow directions around the signal lines S1, S2, S5 and S6 represent the direction of the magnetic field caused by the crosstalk to the signal line S3. Since the signal lines S1, S2, S5 and S6 are all configured as TX signal lines, the communication signal transmission directions of the signal lines S1, S2, S5 and S6 are the same as each other, and thus the directions of the magnetic field caused by the crosstalk to the signal line S3 will also be the same as each other. In this case, the crosstalk of the signal lines S1 and S5 to the signal line S3 will satisfy the condition of constructive interference, and the crosstalk of the signal lines S2 and S6 to the signal line S3 will also satisfy the condition of constructive interference, thereby affecting the signal transmission of the signal line S3.

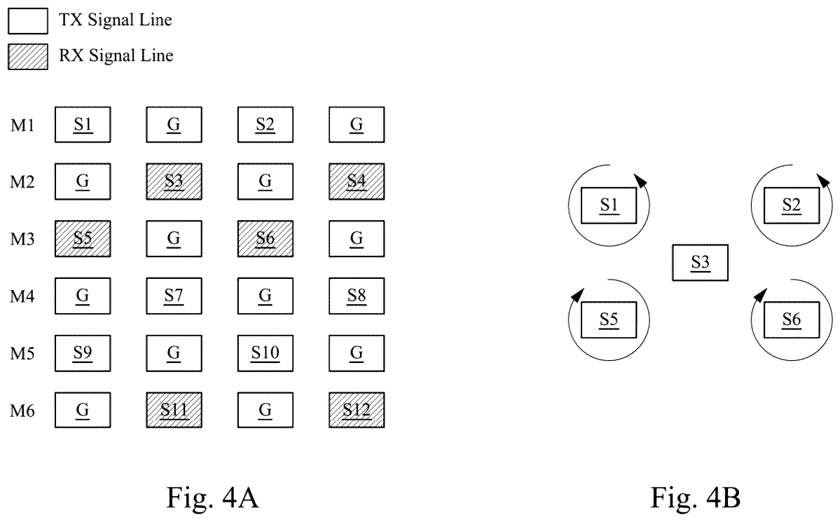

In order to solve the aforementioned phenomenon, the present disclosure provides other configurations of communication signal transmission directions. Please refer to FIG. 4A. FIG. 4A is a schematic diagram of the communication signal transmission direction within the interposer device 110 in accordance with some embodiments of the present disclosure.

In some embodiments, the communication signal transmission directions of each signal line buried in the same circuit layer are the same as each other. Take the embodiment of FIG. 4A as an example, the signal lines S1 and S2 in the circuit layer M1 have the same communication signal transmission direction, the signal lines S3 and S4 in the circuit layer M2 have the same communication signal transmission direction, and so on.

In the embodiment of FIG. 4A, the signal lines S1 and S2 in the uppermost circuit layer M1 are configured as TX signal lines, the signal lines S3-S6 in the circuit layers M2 and M3 are configured as RX signal lines, the signal lines S7-S10 in the circuit layers M4 and M5 are configured as TX signal lines, and the signal lines S11 and S12 in the lowest circuit layer M6 are configured as RX signal lines. Therefore, the circuit layers M1, M4 and M5 are configured to transmit communication signals, and the circuit layers M2, M3 and M6 are configured to receive communication signals. Furthermore, the chip C1 can transmit communication signals to the chip C2 through the signal lines S1, S2 and S7-S10 in the circuit layers M1, M4 and M5, and receive communication signals from the chip C2 through the signal lines S3-S6 and S11-S12 in the circuit layers M2, M3 and M6.

In some embodiments not shown, the configuration of the communication signal transmission direction of the interposer device 110 may be opposite to that of the embodiment of FIG. 4A. In other words, the interposer device 110 can be configured such that the circuit layers M1, M4 and M5 are configured to receive communication signals, and the circuit layers M2, M3 and M6 are configured to transmit communication signals.

FIG. 4B is a schematic diagram of the crosstalk phenomenon around the signal line S3 in accordance with the embodiment of FIG. 4A. In FIG. 4B, the arrow directions around the signal lines S1, S2, S5 and S6 represent the direction of the magnetic field caused by the crosstalk to the signal line S3. Since the signal lines S1 and S2 are configured as TX signal lines, while the signal lines S5 and S6 are configured as RX signal lines, the communication signal transmission directions of the signal lines S1 and S2 will be opposite to the communication signal transmission directions of the signal lines S5 and S6, and thus the directions of the magnetic field caused by the crosstalk to the signal line S3 will also be opposite (as shown in FIG. 4B). In this case, the crosstalk of the signal lines S1 and S5 to the signal line S3 will satisfy the condition of destructive interference, and the crosstalk of the signal lines S2 and S6 to the signal line S3 will also satisfy the condition of destructive interference. Therefore, through this configuration of the communication signal transmission directions, the impact of the crosstalk caused by the signal lines S1, S2, S5 and S6 to the signal line S3 can be alleviated, thereby effectively improving the quality of communication signals in the signal line S3.

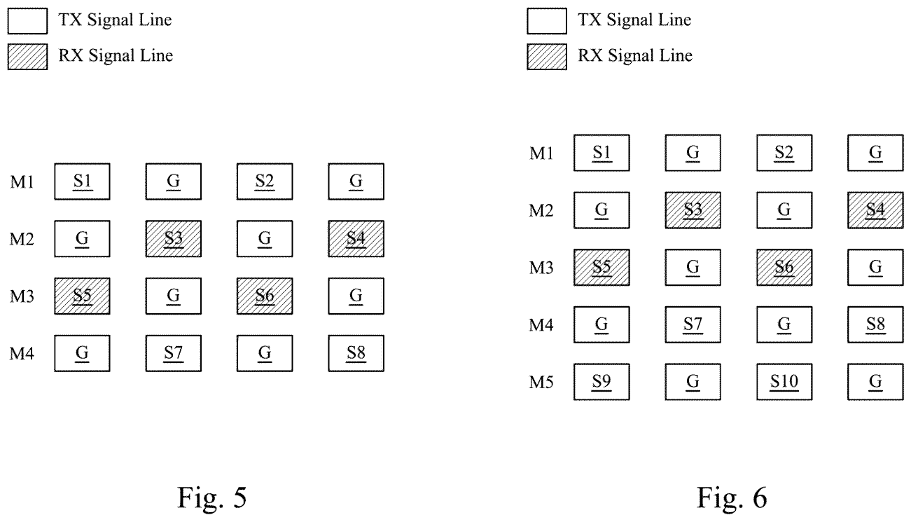

In some embodiments, there may be other numbers of circuit layers in the interposer device 110. Please refer to FIG. 5. FIG. 5 is a schematic diagram of the communication signal transmission direction within the interposer device 110 in accordance with other embodiments of the present disclosure.

In the embodiment of FIG. 5, the interposer device 110 only comprises four circuit layers (i.e., the circuit layers M1-M4). The signal lines S1 and S2 in the uppermost circuit layer M1 are configured as TX signal lines, the signal lines S3-S6 in the circuit layers M2 and M3 are configured as RX signal lines, and the signal lines S7 and S8 in the lowermost circuit layer M4 are configured as TX signal lines. Therefore, the circuit layers M1 and M4 are configured to transmit communication signals, while the circuit layers M2 and M3 are configured to receive communication signals. Furthermore, the chip C1 can transmit communication signals to the chip C2 through the signal lines S1, S2, S7 and S8 in the circuit layers M1 and M4, and receive communication signals from the chip C2 through the signal lines S3-S6 in the circuit layers M2 and M3.

In some embodiments not shown, the configuration of the communication signal transmission direction of the interposer device 110 may be opposite to that of the embodiment of FIG. 5. In other words, the interposer device 110 can be configured such that the circuit layers M1 and M4 are configured to receive communication signals, and the circuit layers M2 and M3 are configured to transmit communication signals.

Based on the embodiments of FIG. 4A and FIG. 5, when the number of circuit layers in the interposer device 110 is an even number, for three circuit layers arranged in sequence, the signal transmission direction of the first circuit layer will be opposite to the signal transmission direction of the last circuit layer. For example, for the circuit layers M1-M3 arranged in sequence, the first circuit layer M1 is configured to transmit communication signals, and the last circuit layer M3 is configured to receive communication signals. In addition, for the uppermost and lowermost circuit layers, their signal transmission directions are opposite to the signal transmission directions of adjacent circuit layers. Take the embodiment in FIG. 5 as an example, the signal transmission direction of the uppermost circuit layer M1 is opposite to that of the adjacent circuit layer M2, and the signal transmission direction of the lowermost circuit layer M4 is opposite to that of the adjacent circuit layer M3.

FIG. 6 is a schematic diagram of the communication signal transmission direction within the interposer device in accordance with yet other embodiments of the present disclosure. In the embodiment of FIG. 6, the interposer device 110 comprises five circuit layers (i.e., the circuit layers M1-M5). The signal lines S1 and S2 in the uppermost circuit layer M1 are configured as TX signal lines, the signal lines S3-S6 in the circuit layers M2 and M3 are configured as RX signal lines, and the signal lines S7-S10 in the circuit layer M4 and the lowermost circuit layer M5 are configured as TX signal lines. Therefore, the circuit layers M1, M4 and M5 are configured to transmit communication signals, while the circuit layers M2 and M3 are configured to receive communication signals. Furthermore, the chip C1 can transmit communication signals to the chip C2 through the signal lines S1, S2, and S7-S10 in the circuit layers M1, M4 and M5, and receive communication signals from the chip C2 through the signal lines S3-S6 in the circuit layers M2 and M3.

In some embodiments not shown, the configuration of the communication signal transmission direction of the interposer device 110 may be opposite to that of the embodiment of FIG. 6. In other words, the interposer device 110 can be configured such that the circuit layers M1, M4 and M5 are configured to receive communication signals, and the circuit layers M2 and M3 are configured to transmit communication signals.

In some embodiments not shown, the interposer device 110 may also be configured such that the circuit layers M1, M2 and M5 are configured to receive communication signals, and the circuit layers M3 and M4 are configured to transmit communication signals; or the circuit layers M1, M2 and M5 are configured to transmit communication signals, and the circuit layers M3 and M4 are configured to receive communication signals.

The embodiment of FIG. 6 is similar to the embodiments of FIGS. 4A and 5 in that when the number of circuit layers in the interposer device 110 is an odd number, among three circuit layers arranged in sequence, the signal transmission direction of the first circuit layer will be opposite to the signal transmission direction of the last circuit layer.

However, what is different from the embodiments of FIGS. 4A and 5 is that when the number of circuit layers in the interposer device 110 is an odd number, for the uppermost and lowermost circuit layers (e.g., the circuit layers M1 and M5 in FIG. 6), the signal transmission direction of one of them is opposite to that of its adjacent circuit layer, while the signal transmission direction of the other one is the same as that of its adjacent circuit layer. As shown in FIG. 6, the signal transmission direction of the uppermost circuit layer M1 is opposite to that of the adjacent circuit layer M2, while the signal transmission direction of the circuit layer M5 is the same as that of the adjacent circuit layer M4.

It should be noted that the number of circuit layers and the number of signal lines and ground lines in each circuit layer in the present disclosure are only examples, and are not intended to limit the present disclosure. Other numbers of circuit layers and other numbers of signal lines and ground lines in each circuit layer are within the scope of the present disclosure when the following configurations are met: (1) among three circuit layers arranged in sequence, the signal transmission direction of the first circuit layer is opposite to the signal transmission direction of the last circuit layer; (2) when the number of circuit layers is an even number, for the uppermost and lowermost circuit layers, their signal transmission directions are respectively opposite to the signal transmission directions of their adjacent circuit layers; and (3) when the number of circuit layers is an odd number, for the uppermost and lowermost circuit layers, the signal transmission direction of one of them is opposite to that of its adjacent circuit layer, while the signal transmission direction of the other one is the same as that of its adjacent circuit layer.

Through the semiconductor package device 100 of the present disclosure, for the interposer device 110 with various numbers of circuit layers, the signal transmission directions of the signal lines in each circuit layer can be set according to specific rules, so that the crosstalk between adjacent signal lines can be reduced due to destructive interference, thereby improving the quality of communication signals in signal lines. In addition, since the semiconductor package device 100 of the present disclosure only changes the configuration of signal transmission directions of the interposer device 110, there is no need to significantly change the internal structure of the semiconductor package device 100, thereby saving manufacturing costs.

The above are preferred embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. An interposer device, configured to provide the transmission of a plurality of communication signals between two chips, wherein the interposer device comprises:
a plurality of circuit layers, electrically connected between the two chips and arranged along a vertical direction, wherein each of the plurality of circuit layers is configured to take a first direction or a second direction as a signal transmission direction for transmitting the plurality of communication signals, wherein the first direction is opposite to the second direction, and both the first direction and the second direction are different from the vertical direction,
wherein each of the plurality of circuit layers comprises a plurality of signal lines and a plurality of ground lines arranged alternately,
the projections of the signal lines in one of the plurality of circuit layers along the vertical direction on an adjacent one of the plurality of circuit layers overlap the plurality of ground lines in the adjacent one of the plurality of circuit layers, and
in any three of the plurality of circuit layers sequentially arranged, the signal transmission direction of the first circuit layer is opposite to the signal transmission direction of the last circuit layer.

2. The interposer device of claim 1, wherein the width of each of the plurality of signal lines is lower than or equal to the width of each of the plurality of ground lines.

3. The interposer device of claim 1, wherein the spacing between each of the plurality of signal lines and an adjacent one of the plurality of ground lines are equal to each other.

4. The interposer device of claim 1, further comprising a redistribution layer, wherein the redistribution layer is disposed above the plurality of circuit layers in the vertical direction and comprises a plurality of signal contacts, and each of the plurality of signal contacts is electrically connected to the two chips through a micro-bump.

5. The interposer device of claim 4, further comprising a plurality of vias, wherein the plurality of vias are buried between the redistribution layer and the plurality of circuit layers, and are configured to electrically connect the plurality of signal contacts to the plurality of signal lines.

6. The interposer device of claim 1, further comprising a ground mesh, wherein the ground mesh is coupled to the plurality of ground lines and configured to provide a ground voltage to the plurality of ground lines, and
wherein the ground mesh comprises two portions at least partially surrounding the plurality of signal lines.

7. The interposer device of claim 1, wherein the number of the plurality of circuit layers is an even number, and
wherein in the vertical direction, the signal transmission direction of the uppermost one of the plurality of circuit layers is opposite to the signal transmission direction of an adjacent circuit layer, and the signal transmission direction of the lowermost one of the plurality of circuit layers is opposite to the signal transmission direction of another adjacent circuit layer.

8. The interposer device of claim 1, wherein the number of the plurality of circuit layers is an odd number, and
wherein in the vertical direction, the signal transmission direction of the uppermost one of the plurality of circuit layers is opposite to the signal transmission direction of an adjacent circuit layer, and the signal transmission direction of the lowermost one of the plurality of circuit layers is same as the signal transmission direction of another adjacent circuit layer.

9. The interposer device of claim 1, wherein the number of the plurality of circuit layers is an odd number, and
wherein in the vertical direction, the signal transmission direction of the uppermost one of the plurality of circuit layers is same as the signal transmission direction of an adjacent circuit layer, and the signal transmission direction of the lowermost one of the plurality of circuit layers is opposite to the signal transmission direction of another adjacent circuit layer.

10. The interposer device of claim 1, further comprising a plurality of dielectric layers, wherein the plurality of dielectric layers are disposed between the plurality of circuit layers and configured to shield the plurality of circuit layers.

11. A semiconductor package device, comprising:
a first chip;
a second chip, configured to transmit a plurality of communication signals with the first chip through a plurality of channels;
a package substrate; and
an interposer device, electrically connected to the first chip, the second chip, the package substrate and comprising a plurality of circuit layers, wherein the plurality of circuit layers are electrically connected between the first chip and the second chip to serve as the plurality of channels and are arranged along a vertical direction, wherein each of the plurality of circuit layers is configured to take a first direction or a second direction as a signal transmission direction for transmitting the plurality of communication signals, wherein the first direction is opposite to the second direction, and both the first direction and the second direction are different from the vertical direction,
wherein each of the plurality of circuit layers comprises a plurality of signal lines and a plurality of ground lines arranged alternately,
the projections of the signal lines in one of the plurality of circuit layers along the vertical direction on an adjacent one of the plurality of circuit layers overlap the plurality of ground lines in the adjacent one of the plurality of circuit layers, and
in any three of the plurality of circuit layers sequentially arranged, the signal transmission direction of the first circuit layer is opposite to the signal transmission direction of the last circuit layer.

12. The semiconductor package device of claim 11, wherein the width of each of the plurality of signal lines is lower than or equal to the width of each of the plurality of ground lines.

13. The semiconductor package device of claim 11, wherein the spacing between each of the plurality of signal lines and an adjacent one of the plurality of ground lines are equal to each other.

14. The semiconductor package device of claim 11, wherein the interposer device further comprises a redistribution layer, the redistribution layer is disposed above the plurality of circuit layers in the vertical direction and comprises a plurality of signal contacts, and each of the plurality of signal contacts is electrically connected to the first chip and the second chip through a micro-bump.

15. The semiconductor package device of claim 14, wherein the interposer device further comprises a plurality of vias, the plurality of vias are buried between the redistribution layer and the plurality of circuit layers, and are configured to electrically connect the plurality of signal contacts to the plurality of signal lines.

16. The semiconductor package device of claim 11, wherein the interposer device further comprises a ground mesh, the ground mesh is coupled to the plurality of ground lines and configured to provide a ground voltage to the plurality of ground lines, and
wherein the ground mesh comprises two portions at least partially surrounding the plurality of signal lines.

17. The semiconductor package device of claim 11, wherein the number of the plurality of circuit layers is an even number, and
wherein in the vertical direction, the signal transmission direction of the uppermost one of the plurality of circuit layers is opposite to the signal transmission direction of an adjacent circuit layer, and the signal transmission direction of the lowermost one of the plurality of circuit layers is opposite to the signal transmission direction of another adjacent circuit layer.

18. The semiconductor package device of claim 11, wherein the number of the plurality of circuit layers is an odd number, and
wherein in the vertical direction, the signal transmission direction of the uppermost one of the plurality of circuit layers is opposite to the signal transmission direction of an adjacent circuit layer, and the signal transmission direction of the lowermost one of the plurality of circuit layers is same as the signal transmission direction of another adjacent circuit layer.

19. The semiconductor package device of claim 11, wherein the number of the plurality of circuit layers is an odd number, and
wherein in the vertical direction, the signal transmission direction of the uppermost one of the plurality of circuit layers is same as the signal transmission direction of an adjacent circuit layer, and the signal transmission direction of the lowermost one of the plurality of circuit layers is opposite to the signal transmission direction of another adjacent circuit layer.

20. The semiconductor package device of claim 11, wherein the interposer device further comprises a plurality of dielectric layers, the plurality of dielectric layers are disposed between the plurality of circuit layers and configured to shield the plurality of circuit layers.
